(19) United States
(12) Patent Application Publication
(10) Pub. No.: US 2026/0223465 A1
(43) Pub. Date: Jul. 30, 2026

(54) SOLAR PANEL WITH POLYCARBONATE EDGE SEAL

(71) Applicant: SAUDI ARABIAN OIL COMPANY, Dhahran (SA)

(72) Inventors: Issam GEREIGE, Dhahran (SA); Konstantinos KOTSOVOS, Dhahran (SA); Sarah AQEEL, Dhahran (SA)

(73) Assignee: SAUDI ARABIAN OIL COMPANY, Dhahran (SA)

(21) Appl. No.: 19/038,457

(22) Filed: Jan. 27, 2025

(51) Int. Cl. H10F 19/80; H02S 30/10

(52) U.S. Cl. CPC H10F 19/804; H02S 30/10

(57) ABSTRACT

A solar panel comprises a photovoltaic module having opposing first and second sides. The solar panel further comprises a first polycarbonate member engaged with the first side of the photovoltaic module. The solar panel further comprises a second polycarbonate member engaged with the second side of the photovoltaic module, the photovoltaic module being disposed between the first and second polycarbonate members. The solar panel further comprises a first polycarbonate edge member disposed in a gap between the first and second polycarbonate members, the first polycarbonate edge member being bonded to the first and second polycarbonate members.

### FIELD OF THE DISCLOSURE

The present disclosure relates generally to photovoltaic solar panels, and more particularly, to systems and methods of sealing the edge around a photovoltaic module of the solar panel.

### BACKGROUND OF THE DISCLOSURE

Solar panels conventionally include a photovoltaic module disposed between opposing covers (layers). The edges around the photovoltaic module sandwiched between the opposing covers are typically filled with a curable liquid sealant to seal the photovoltaic module from the outside environment. Conventional curable edge sealants include ethylene vinyl acetate (EVA), silicon, butyl rubber, and polyurethane.

Solar panels are used in the outdoor environment to maximize exposure to the sun. Consequently, solar panels is exposed to moisture in the form of rain, humid air, fog and, depending on the location, snow, as well as other forms of atmospheric precipitation. Additionally, the solar panel is exposed to particulates in the air, such as dust, as well as being exposed to ultraviolet rays. Photovoltaic modules will degrade in performance if moisture and/or particulate is allowed to come in contact with the photovoltaic elements of the photovoltaic module. Such degradation is usually gradual and irreversible. Eventually, the photovoltaic module may experience sufficient degradation necessitating its replacement.

Conventional edge sealants for solar panels are susceptible to degradation over time due to the environmental conditions (e.g., moisture, ultraviolet light, and/or particulate in the air). Degradation of the edge sealant can result in the formation of leak paths that allow the photovoltaic module to become exposed to the environment, which will lead to the degradation of the photovoltaic module.

Accordingly, there exists a need in the art for improved edge sealing of solar panels to increase the longevity of the photovoltaic module.

### SUMMARY OF THE DISCLOSURE

Various details of the present disclosure are hereinafter summarized to provide a basic understanding. This summary is not an extensive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to an embodiment consistent with the present disclosure, a solar panel comprises a photovoltaic module having opposing first and second sides. The solar panel further comprises a first polycarbonate member engaged with the first side. The solar panel further comprises a second polycarbonate member engaged with the second side, the photovoltaic module being disposed between the first and second polycarbonate members. The solar panel further comprises a first polycarbonate edge member disposed in a gap between the first and second polycarbonate members, the first polycarbonate edge member being bonded to the first and second polycarbonate members.

According to an embodiment consistent with the present disclosure, a solar panel comprises a first polycarbonate member defining a recess disposed between a first interface surface and a second interface surface. The solar panel further comprises a second polycarbonate member contacting the first and second interface surfaces. The solar panel further comprises a photovoltaic module disposed in the recess between the first and second polycarbonate members.

According to an embodiment consistent with the present disclosure, a solar panel comprises a first polycarbonate member having opposing first and second ends, and opposing first and second surfaces. The solar panel further comprises a second polycarbonate member having opposing first and second ends, and opposing first and second surfaces. The solar panel further comprises a photovoltaic module disposed between the first and second polycarbonate members, the first and second polycarbonate members being arranged such that the first surface of the first polycarbonate member opposes the first surface of the second polycarbonate member. The solar panel further comprises a first polycarbonate edge member defining a first recess sized to receive the first ends of the first and second polycarbonate members. The solar panel further comprises a second polycarbonate edge member defining a second recess sized to receive the second ends of the first and second polycarbonate members.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is an isometric view of an example solar panel that may incorporate the principles of the present disclosure.

FIG. 2A is a schematic cross-sectional view of a solar panel.

FIG. 2B is a schematic cross-sectional view of the solar panel of FIG. 2B prior to inserting the edge members into the edge gap.

FIG. 2C is a schematic cross-sectional view of the solar panel of FIG. 2A showing a laser welding of an interface of the edge member.

FIG. 3A is a schematic cross-sectional view of a solar panel prior to bonding a first member onto a second member.

FIG. 3B is a schematic cross-sectional view of the solar panel of FIG. 3A showing the first member bonded to the second member.

FIG. 3C is a schematic top view of a second member of the solar panel of FIG. 3A.

FIG. 4A is a schematic cross-sectional view of a solar panel prior to bonding edge members to first and second members of the solar panel.

FIG. 4B is a schematic cross-sectional view of the solar panel of FIG. 4A showing the edge members bonded to an outer side of the first and second members.

FIG. 4C is a top view of the solar panel of FIG. 4A showing the first and second members framed within four edge members.

FIG. 4D is a side view of an edge member of the solar panel of FIG. 4C that covers a top and a bottom ends of the solar panel.

FIG. 5A is a schematic cross-sectional view of a solar panel prior to bonding edge members to a first and second member of the solar panel.

FIG. 5B is a schematic cross-sectional view of the solar panel of FIG. 4A showing the edge members bonded to both an outer and inner side of the first and second members.

FIG. 6A is a schematic cross-sectional view of a solar panel prior to injecting a liquid polycarbonate between first and second members of the solar panel.

FIG. 6B is a schematic cross-sectional of the solar panel of FIG. 6A after the liquid polycarbonate solidifies to form a polycarbonate edge member.

FIG. 7 is a schematic flowchart illustrating an example method of forming a solar panel.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments in accordance with the present disclosure generally relate to solar panels and, more particularly, to systems and methods of sealing the edge around a photovoltaic module of the solar panel. More specifically, the present disclosure relates to using polycarbonate to seal the edge around the photovoltaic module sandwiched between first and second polycarbonate members (layers) of the solar panel. The edge may be sealed by bonding a polycarbonate edge member that has been inserted into a gap at the edge between the overhanging first and second members of the solar panel. In some embodiments, the seal is provided by bonding a polycarbonate member (e.g., end cap) to the ends of the first and second members. In some embodiments, the seal is provided by injecting a liquid polycarbonate into the gap at the edge between the overhanging first and second members which later cools to form a robust seal around the edge of the photovoltaic module.

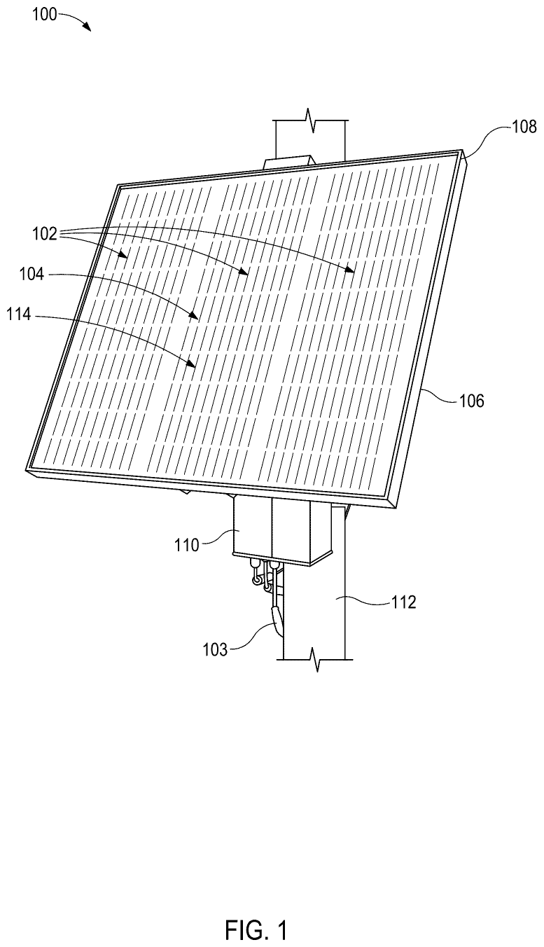

FIG. 1 is an isometric view of an example solar panel 100 that may incorporate the principles of the present disclosure. The solar panel 100 functions to convert sunlight into electrical energy through a process known as the photovoltaic (PV) effect. The solar panel 100 includes a front layer 104 (e.g., first member), a back layer 106 (e.g., second member), and a plurality of photovoltaic elements 102 (e.g., photovoltaic cells) interposing the front and back layers 104, 106. At least the front layer 104 is made of a transparent material that allows sunlight to pass therethrough and impinge on the photovoltaic elements 102.

The photovoltaic elements 102 convert light into electricity. The photovoltaic elements 102 may be made from semiconductor materials like silicon, for example. When sunlight strikes the photovoltaic elements 102, it excites electrons in the semiconductor material, causing them to break free from their atoms. The free electrons are collected by a conductive grid made of materials like silver or aluminum, for example, which is applied to the surface of the photovoltaic elements 102. These electrons then flow through wires that connect the individual elements 102 in series or parallel configurations, forming a circuit and generating direct current (DC) electricity. This DC electricity may then be converted to alternating current (AC) using an inverter, making it suitable for use in applications like powering an oil and natural gas platform.

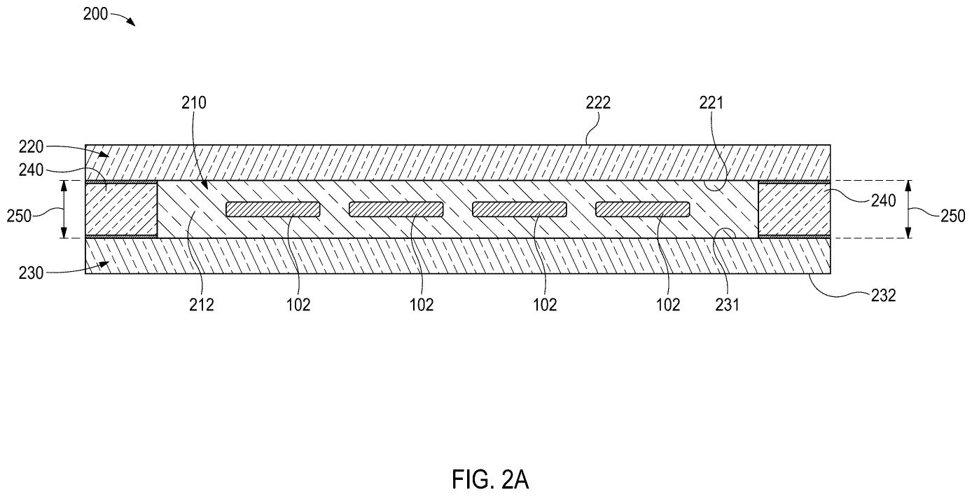

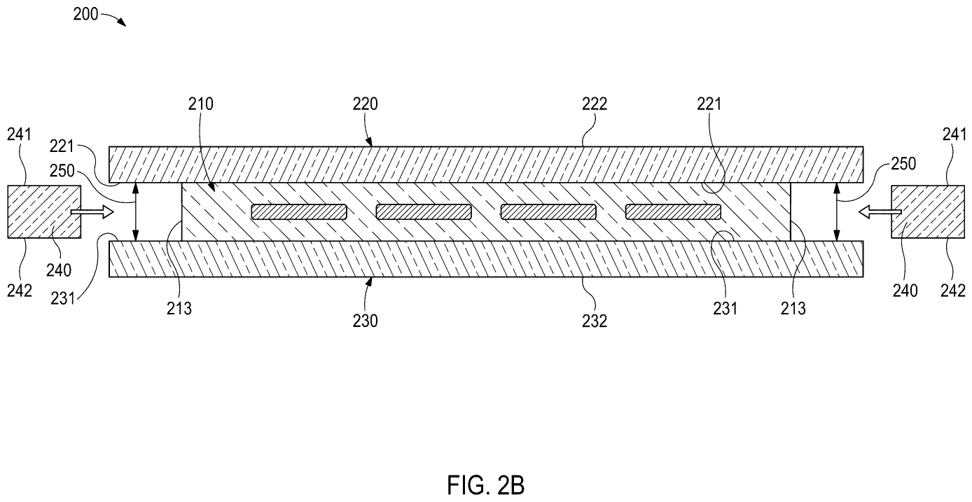

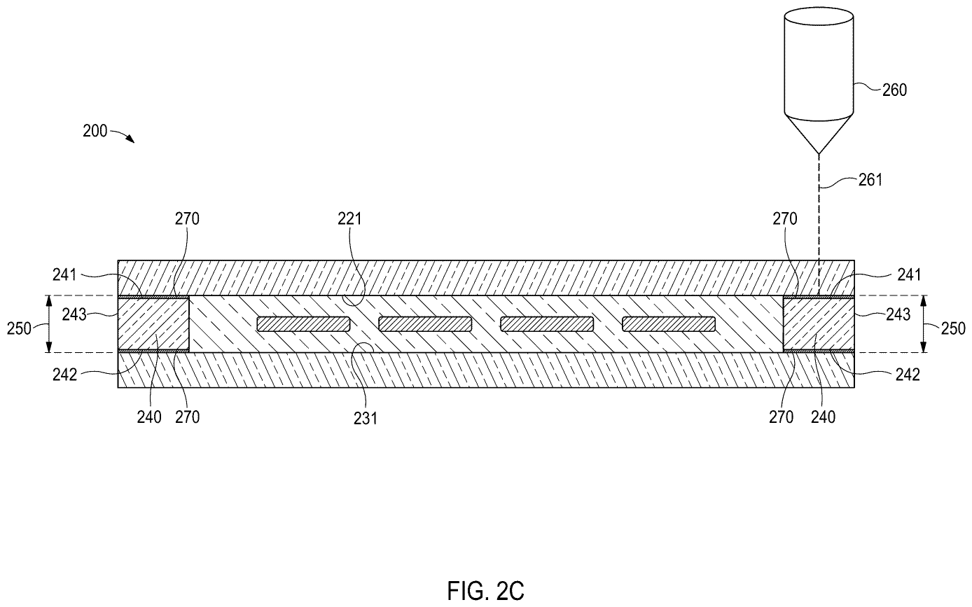

The photovoltaic elements 102 may be encapsulated between the transparent front layer 104 and the back layer 106, each of which may be made of a polycarbonate material, to protect against environmental factors and mechanical stress. The photovoltaic elements 102 may form part of a photovoltaic module, such as photovoltaic module 210 (FIG. 2A), sandwiched between the front layer 104 and the back layer 106. For example, the photovoltaic module 210 may include the photovoltaic elements 102 embedded in a polymer encapsulant 212 (FIG. 2A) to protect the photovoltaic elements from environmental conditions.

The solar panel 100 may further include a frame 108 to enclose the photovoltaic elements 102 and the front and back layers 104, 106. The frame 108 may provide structural support and facilitate mounting and installation of the solar panel 100. In some embodiments, the frame 108 may include a transparent front layer 114 (i.e., the “face” of the solar panel 100), which may be made of tempered glass, for example, and may be arranged atop the transparent front layer 104 such that sunlight may reach the photovoltaic elements 102 via the transparent layers 104, 114.

The solar panel 100 may further include a junction box 110 that may be mounted to the frame 108. The junction box 110 may house electrical connections and diodes that prevent backflow of current. In some applications, the solar panel 100 and the junction box 110 may be mounted to a support 112, such as a pole, for example, to elevate the solar panel 100 above the ground so that it can be oriented toward the sun.

The solar panel 100 is exposed to outside environmental conditions, such as the ultraviolet light of the sun, humidity, precipitation, wind, temperature, and particulate matter (e.g., dust) suspended in the air. The photovoltaic elements 102 can degrade when exposed to the outside environment, such as in response to water (e.g., humidity) reacting with the photovoltaic elements 102. The encapsulant that the photovoltaic elements 102 are embedded within is susceptible to degradation by environmental conditions, such as degrading due to ultraviolet light exposure, which can lead to the formation of leak paths that expose the photovoltaic elements to the outside environment. The edge around the polymer encapsulant sandwiched between the front layer 104 and the back layer 106 is therefore advantageously sealed by polycarbonate rather than a conventional curable edge sealant.

In some embodiments, as described in more detail below, the seal is provided by bonding a polycarbonate edge member that has been inserted into a gap at the edge between overhanging portions of the front and back layers 104, 106. In some embodiments, the seal is provided by bonding a polycarbonate end cap to the ends of the front and back layers 104, 106. In some embodiments, the seal is provided by injecting a liquid polycarbonate into the gap at the edge between overhanging portions of the front and back layers 104, 106, which later cools to form a robust seal around the edge of the encapsulant.

The edge seal described herein by the bonded polycarbonate or solidified polycarbonate provides a more robust and durable seal from environmental conditions as opposed to conventional edge sealants that are prone to degradation in response to environmental conditions (e.g., humidity, precipitation, temperatures, particulate matter, and ultraviolet light). In other words, the polycarbonate seal described herein allows for the solar panel 100 to be reliably used in harsh conditions with improved longevity.

FIGS. 2A-2C illustrate schematic cross-sectional views of an exemplary solar panel 200 used to generate electricity in response to light emanating from a light source, such as the sun. The solar panel 200 may be the same as or similar to the solar panel 100 of FIG. 1 and, therefore, may be disposed in the frame 108 (FIG. 1) once assembled and thereafter mounted to the support 112 (FIG. 1). Moreover, the solar panel 200 includes a photovoltaic module 210, a first member 220 (e.g., a front member, a first sheet, a first substrate, a first layer, etc.), a second member 230 (e.g., a back member, a second sheet, a second substrate, a second layer, etc.), and edge members 240. The first member 220 may be the same as or similar to the front layer 104 (FIG. 1) and the back member 230 may be the same as or similar to the back layer 106 (FIG. 1). The edge members 240 are disposed between and bonded to the first and second members 220, 230 to seal the photovoltaic module 210 from the outside environment. In some embodiments, the first member 220 may be directed toward the light source and is formed of a material that allows the light to pass therethrough and reach the photovoltaic module 210.

FIG. 2A illustrates a cross-sectional view of the assembled solar panel 200 assembled after the edge members 240 are bonded to the first and second members 220, 230. The photovoltaic module 210 includes at least one photovoltaic element 102, such as a plurality of photovoltaic elements 102 embedded within an encapsulant 212. The encapsulant 212 may be a polymer material, such as an organic polymer or a thermoplastic. The encapsulant 212 seals (e.g., protects) the photovoltaic elements 102 from the outside environment. However, the encapsulant 212 can degrade over time due to the environmental conditions present where the solar panel 200 is located. For example, the heat, humidity, and ultraviolet light can degrade the encapsulant 212 such that a leak path develops within the encapsulant that exposes one or more of the photovoltaic elements 102 to the environment. Breakdown in the encapsulant 212 can therefore lead to the degradation of the photovoltaic elements 102 in response to humidity, water, or other particulate in the atmosphere reaching the photovoltaic elements 102 through leak paths that have formed within the encapsulant 212.

As shown in FIG. 2A, the photovoltaic module 210 is disposed (e.g., sandwiched) between the first and second members 220, 230. The photovoltaic module 210 is engaged with a first or “inner” surface 221 (e.g., first side) of the first member 220 and a first or “inner” surface 231 (e.g., first side) of the second member 230. The first member 220 has a second or “outer” surface 222 (e.g., second side) opposite the first surface 221, and the second member 230 similarly has a second or “outer” surface 232 (e.g., second side) opposite the first surface 231.

The edge members 240 are inserted into an edge gap 250 (FIG. 2B) defined between overhanging portions of the first and second members 220, 230 to seal a respective edge of the solar panel 200. The edge member 240 may be a strip of material (e.g., a strip of polycarbonate) sized to fit into the edge gap 250. The interface between the edge members 240 and the first and second members 220, 230 are bonded together to further seal the photovoltaic module 210 from the environment. For example, the interface may be bonded by a thermal welding process, a laser welding process, or a chemical process. Bonding the edge members 240 to the first and second members 220, 230 forms a durable edge seal that is less susceptible to degradation than conventional curable liquid sealants used to seal the edges around conventional solar panels. Bonding the edge members 240 to the first and second members 220, 230, therefore, provides the solar panel 200 with increased longevity and usability in harsher conditions as compared to conventional liquid edge sealants.

In some embodiments, the first and second members 220, 230 and the edge members 240 are formed from the same material. In some embodiments, the first and second members 220, 230 are formed from a polycarbonate material (e.g., polycarbonate sheet), such as being formed from the same polycarbonate material. The edge members 240 may similarly be formed from a polycarbonate material, such as being the same material as the first and second members 220, 230.

FIGS. 2B and 2C are cross-sectional side views illustrating an example process of assembling the solar panel 200. As shown in FIG. 2B, the photovoltaic module 210 is sandwiched between the first and second members 220, 230 prior to installing the edge members 240. The length of first and second members 220, 230 is greater than the length of the photovoltaic module 210 such that portions of the first and second members 220, 230 extend past the lateral edges of the photovoltaic module 210. Moreover, the first and second members 220, 230 are offset from teach other, thereby defining the edge gap 250 between the opposing overhanging portions of the first and second members 220, 230. As shown, each edge gap 250 is defined by an exterior surface 213 of the photovoltaic module 210, an overhanging portion of the inner surface 221 of the first member 220, and an overhanging portion of the inner surface 231 of the second member 230 that directly opposes the inner surface 221.

Each edge member 240 is inserted into a corresponding (adjacent) edge gap 250 in the direction of the arrows shown in FIG. 2B such that a first interface surface 241 of the edge member 240 can be bonded to the inner surface 221, and a second interface surface 242 of the edge member 240 can be bonded to the inner surface 231.

FIG. 2C illustrates the edge members 240 inserted into (received within) a respective edge gap 250. In some embodiments, the edge members 240 exhibit a thickness that is at least equal to the thickness of the edge gap 250 such that a clearance is not present when the edge member 240 is inserted into the corresponding edge gap 250. In other words, the edge member 240 may be in contact with both of the first and second members 220, 230 prior to forming the bond. In at least one embodiment, inserting the edge members 240 into the corresponding edge gap 250 may form an interference fit. In other embodiments, however, the edge members 240 may be sized such that a small clearance is present between the edge member 240 and one of the first and second members 220, 230 prior to bonding the edge member 240 to the first and second members 230, 240. The clearance, however, is closed when the interface surfaces 241, 242 are bonded with the respective surface 221, 232. In some embodiments, and as shown in FIG. 2C, the edge members 240 are sized such that an exterior edge surface 243 (e.g., end) thereof is flush with the ends of the first and second members 220, 230 when inserted into the respective edge gap 250.

FIG. 2C shows bonding the edge members 240 to the first and second members 220, 230 by laser welding (e.g., laser melting). A laser welding device 260 directs a laser beam 261 toward the interface being bonded together. For example, the laser beam 261 is directed at the first interface surface 241 of the edge member 240 shown on the right-hand side of the figure through the first member 220. The laser beam 261 causes localized heating in the first member 220 and the edge member 240 which melts a portion of the first member 220 and the edge member 240 to form a weld line 270 (e.g., a mechanical bond). The second interface surface 242 can be bonded to the second surface 232 of the second member 230 in a similar manner. The localized heating provided by the laser welding device 260 allows for the weld line 270 to be formed without heating the entire solar panel 200, which avoids exposing the photovoltaic module 210 to temperatures that could degrade the photovoltaic elements 102 and/or the encapsulant 212.

In some embodiments, the weld 270 can be formed along the entire width of the interface between the edge member 240 and the first and second members 220, 230 as shown in FIG. 2C. In other words, the weld 270 may extend from the exterior edge to the inner edge of the of the interface surfaces 241, 242. In some embodiments, the weld 270 may instead only extends a portion of the width of the interface surfaces 241, 242. For example, the weld 270 may be a weld bead extending along the exterior edge of the interface between the edge member 270 and the first and second members 220, 230.

In alternative embodiments, the edge members 240 may be mechanically bonded (e.g., welded) to the first and second members 220, 230 using different localized heating techniques, such as using resistive heating elements to melt the interface rather than using the laser welding device 260, thereby resulting in the weld line 270.

In yet other embodiments, the edge members 240 and first and second members 220, 230 may instead be chemically bonded together, and thereby also resulting in the weld line 270. For example, a chemical such as ethylene chloride, chloroform, or tetrachloroethane may be locally applied to briefly dissolve the polycarbonate material and thereby facilitate cross-linking the edge member 240 to the first and second members 220, 230. Using a chemical process avoids the risk of the degrading the photovoltaic module 210 due to heat transfer from the localized heating process. The mechanical bond or a cross-linked bond between the edge member 240 and the first and second members 220, 230 provides a more durable seal than conventional liquid edge sealants.

In some embodiments, the interface surfaces 241, 242 and/or the first and second surfaces 221, 232 may be etched prior to performing a bonding operation to enhance the strength of the bond, such as the weld, between the edge member 240 and the first and second members 220, 230.

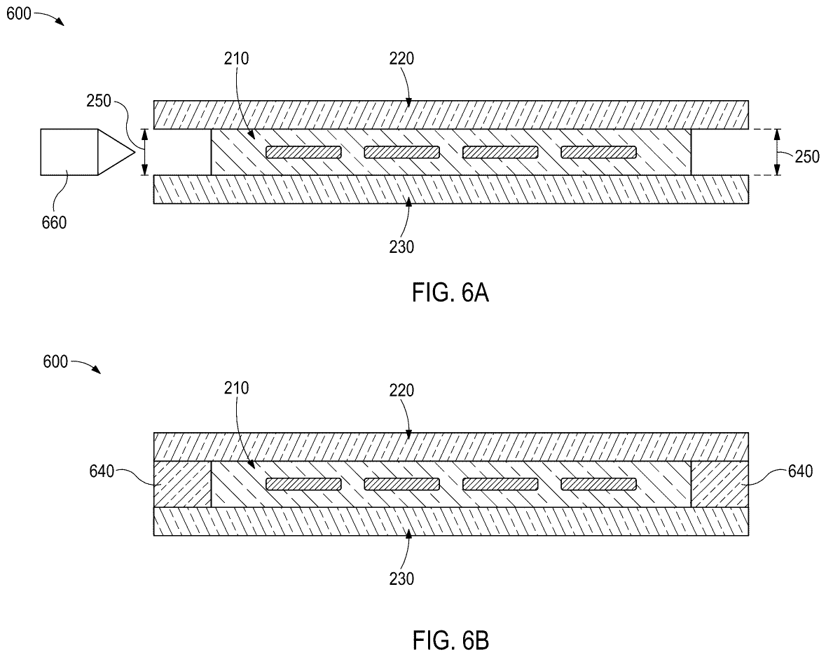

While FIGS. 2A-2C illustrate two edge members 240 on the right and left hand side of the solar panel 200, the top and bottom edges of the solar panel 200 may similarly be sealed using an edge member 240 that is bonded to the first and second members 220, 230. The top and bottom edges, however, may instead sealed by injecting a liquid polycarbonate as described herein with reference to FIGS. 6A-6B.

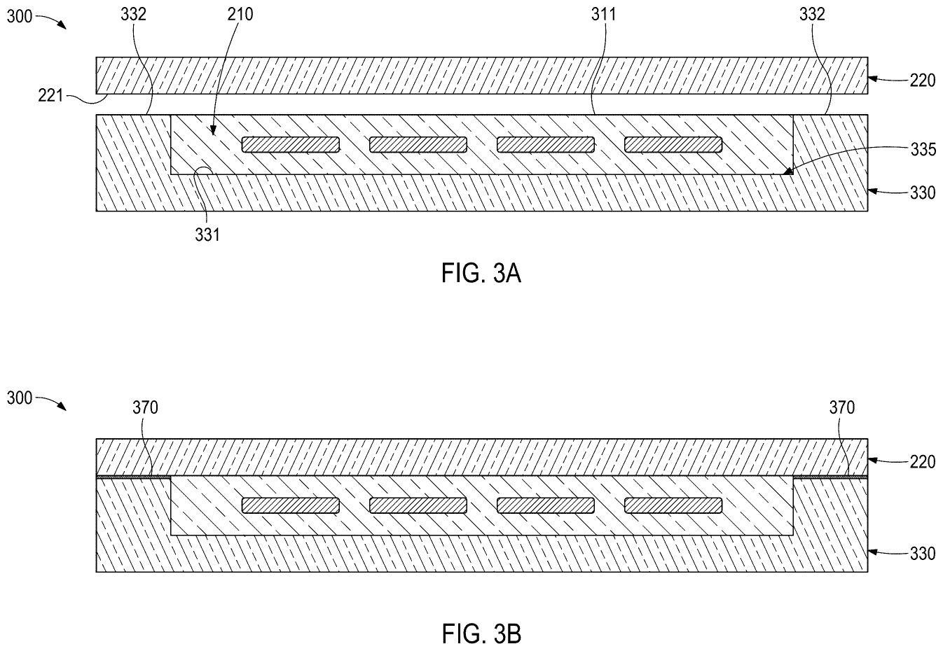

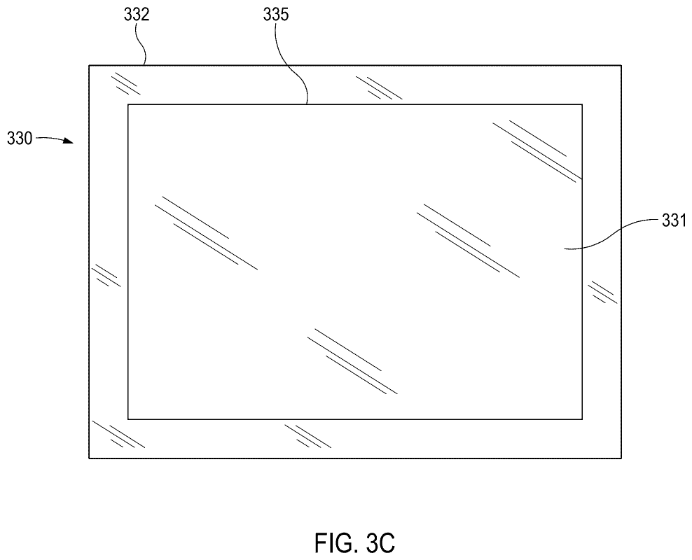

FIGS. 3A and 3B illustrate schematic cross-sectional views of another example solar panel 300 that may incorporate the principles of the present disclosure. The solar panel 300 may be similar in some respects to the solar panel 200 of FIGS. 2A-2C and, therefore, may be best understood with reference thereto, where like numerals will correspond to like components not described again in detail. Similar to the solar panel 200, for instance, the solar panel 300 includes the photovoltaic module 210 and the first member 220. The solar panel 300 may further include a second member 330, and a bond 370 (FIG. 3B) is formed at the interface between the first and second members 220, 330 to seal the photovoltaic module 210 from the outside environment.

Referring first to FIG. 3A, illustrated is a semi-exploded view of the solar panel 300. As illustrated, the second member 330 may exhibit a generally U-shaped cross-section with a recess 335 being formed on a first side 331 (e.g., inner surface, first surface) of the second member 330. To form the solar panel 300, the photovoltaic module 210 is placed in the recess 335 and then the first sheet 220 is engaged with portions of the first side 331 on opposing sides of the recess 335. More specifically, the first surface 221 of the first member 220 is engaged with corresponding second surfaces 332 of the first side 331 that are disposed on opposing sides of the recess 335. The surfaces 221, 332 are thereafter bonded together, such as by localized heating (e.g., welding) or a chemical process (e.g., cross-linking the components together) to attach the first member 220 to the second member 330, which beneficially seals the photovoltaic module 210 from the outside environment. The surfaces 221, 332 may also be etched prior to performing a bonding process.

FIG. 3B illustrates an assembled solar panel 300 with the first member 220 attached to the second member 330 via bonds 370. The solar panel 300 has less components than the solar panel 200 shown in FIGS. 2A-2C, in that the separate edge members that are inserted into a corresponding edge gap are omitted. Rather, the first member 220 and the second member 330 are directly bonded together.

In some embodiments, the first and second members, 220 330 are formed from the same material, such as being formed from a polycarbonate material (e.g., polycarbonate sheet). In some embodiments, and as shown in FIG. 3A, the recess 335 has a depth that is equivalent to the thickness of the photovoltaic module 210 such that the interface surfaces 332 are substantially flush with an exterior surface 311 of the photovoltaic module 210.

In some embodiments the recess 335 is bounded entirely by a continuous second surface 332. FIG. 3C illustrates a schematic top view of the second member 330 that shows the recess 335 formed on the first side 331 bounded by the second surface 332. In other words, the recess 335 does not extend all the way from the top to the bottom ends of the second member 330 such that wall formed by the second member 330 extends along the entire perimeter of the recess 335. Bounding the recess 335 around the entire perimeter with the second surface allows for a continuous bond 370 to be formed around the entire perimeter of the recess 335 to seal in the photovoltaic module 210.

In some embodiments, the recess 335 may extend from the top end to the bottom end of the second member 330 rather than being bounded by a continuous second surface 332 such that an edge gap will be present at the top and bottom edges between the second member 330 and the first member 120. The top and bottom edges of the solar panel 300 may be sealed by inserting an edge member, such as edge member 240, into the top and bottom edge gaps. The edge member may then be bonded to the first and second members 220, 320 to seal the top and bottom edges. The top and bottom edges, however, may instead sealed by injecting a liquid polycarbonate as described in FIGS. 6A-6B.

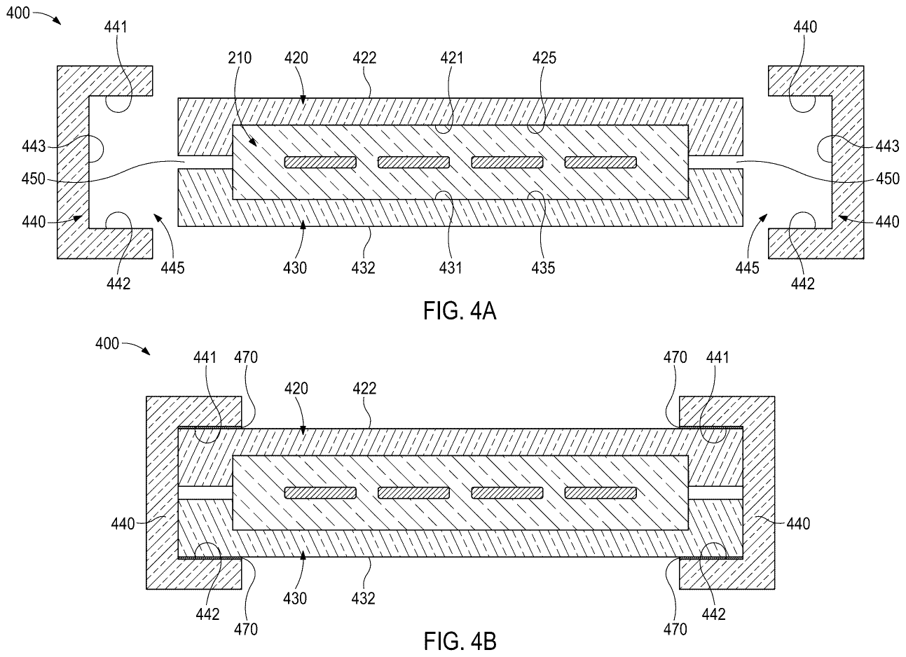

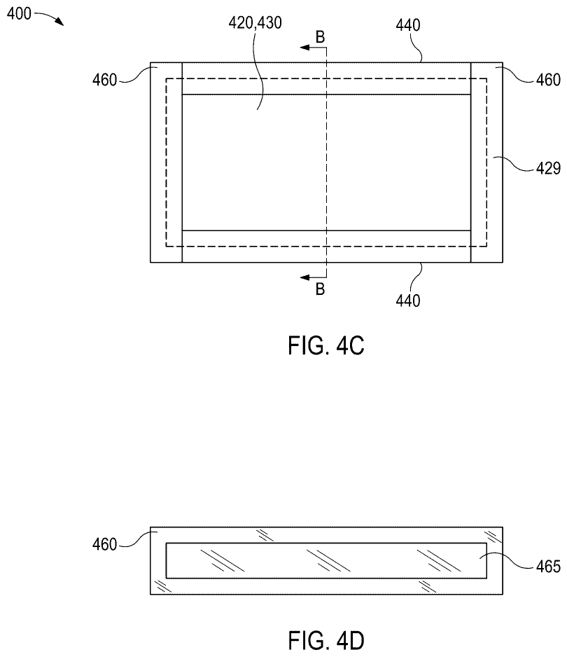

FIGS. 4A and 4B illustrate another example solar panel 400 that may incorporate one or more principles of the present disclosure. The solar panel 400 may be similar in some respects to the solar panel 200 of FIGS. 2A-2C and, therefore, may be best understood with reference thereto, where like numerals will correspond to like components not described again in detail. Similar to the solar panel 200, for instance, the solar panel 400 includes the photovoltaic module 210. The solar panel 400 also includes a first member 420, a second member 430, and edge members 440 (e.g., end caps). In some embodiments, the first member 420, the second member 430, and the edge member 440 may be formed from the same material, such as a polycarbonate material. The edge members 440 are bonded (see bond 470 in FIG. 4B) to an outer side (e.g., sides 422, 432) of the first and second members 420, 430 while the photovoltaic module 210 is disposed between opposing inner sides (e.g., sides 421, 431) of the first and second members 420, 430. Bonding the edge members 440 to the first and second members 420, 430 seals the photovoltaic module 210 from the outside environment.

FIG. 4A illustrates a semi-exploded view of the solar panel 400. As shown, the first and second members 420, 430 are generally U-shaped, with the first member 420 defining a recess 425 formed on an inner side 421 (e.g., first side), and the second member 430 similarly defining a recess 425 formed on an inner side 431 thereof. The photovoltaic module 210 is cooperatively received within the recesses 425, 435 when the solar panel 400 is assembled.

The edge members 440 are U-shaped with an edge recess 445 formed on one side thereof that is sized to receive ends (e.g., edges) of the first and second members 420, 430. More specifically, the edge recess 445 is defined by a first recess surface 441, a second recess surface 442, and a third recess surface 443 (e.g., end surface) that separates the first and second recess surfaces 441, 442 from one another. The first recess surface 441 is engageable with an outer side 422 of the first member 420 and the second recess surface 442 is engageable with an outer side 432 of the second member 430 when the first and second members 420, 430 are inserted into the edge recess 445. In some embodiments, the recess 445 extends the length of the edge member 440. However, the recess 445 may, in some embodiments, only extend a portion of the length of the edge member 440 such that a portion of the top and bottom edge gaps of the solar panel 400 are covered by the edge member 440.

To assemble the solar panel 400, the photovoltaic module 210 is disposed (e.g., sandwiched) between the first and second members 420, 430 that are arranged such that the inner sides 421, 431 oppose one another as shown in FIG. 4A. In some embodiments, a gap 450 may be present between opposing portions of the inner sides 421, 431 on either side of the respective recess 425, 435 when the photovoltaic module 210 is placed between the first and second members 420, 430. In some embodiments, the first and second members 420, 430 may contact one anther rather than being separated by the gap 450.

After sandwiching the photovoltaic module 210 between the first and second members 430, 440, the edge members 440 are then installed over the ends of the first and second members 430, 440 by receiving the ends of the first and second members 430, 440 within the edge recess 445 of the adjacent edge members 440. The edge members 440 are then bonded to the first and second members 420, 430 using a bonding process, such as localized heating process to weld surfaces together or a chemical process to crosslink the edge members 440 with the first and second members 420, 430. The surfaces being bonded together may be etched prior to performing the bonding process to enhance the strength of the bond. The bond, which may be a mechanical bond or a cross-linked bond, provides a more durable seal than conventional liquid sealants.

FIG. 4B illustrates the assembled solar panel 400 showing the bonds 470 between the edge members 440 and the first and second members 420, 430. FIG. 4B illustrates the cross-sectional view of the solar panel along section line B-B in FIG. 4C. The bonds 470 seal the photovoltaic module 210 from the outside environment. The first recess surface 441 of each edge member 440 is affixed to outer side 422 of the first member 430 by bond 470. The second recess surface 442 of each edge member 440 is similarly affixed to the outer side 432 of the second member 430 by bond 470. In some embodiments, the third recess surface 443 may be also be fully or partially bonded to the edges of the first and second members 420, 430. The edge members 430, in addition to protecting the photovoltaic module 210 from the outside environment, provide improved structural stability to the solar panel 400 since the edge members 430 resist bending of the solar panel 400.

In some embodiments, the third recess surface 443 may be engaged with the edges of the first and second members 420, 430 when the solar panel 400 is assembled. However, a clearance may be present between the third recess surface 443 and the first and second members 420, 430 in some embodiments of the assembled solar panel 400.

It should be noted that while FIGS. 4A-4B illustrate an edge member 440 on the left and right-hand side of the solar panel 400, the top and bottom edges of the solar panel 400 (e.g., gap between the first member 420 and second member 430 at the top and bottom ends of the solar panel) may also be sealed by bonding an appropriately sized edge member at either the top end or bottom edge. In some embodiments, the top and bottom edges of the solar panel 400 are sealed using edge members with a recess that extends across only a portion of the edge member such that an edge member is inserted over each edge of the first and second members 420, 430.

FIG. 4C is a top view of the solar panel 400 and shows the solar panel 400 having each edge of the first and second members 420, 430 enclosed by a corresponding edge member. In other words, the first and second members 420, 430 are framed within four edge members. The periphery of the first member 420 (or the second member 430) is shown by dashed line 429. The left and right hand sides of the solar panel 400 are enclosed by edge members 440 while the top and bottom edges are enclosed by edge members 460 (e.g., end caps). The edge members 460 are similar to edge members 440, but a recess 465 (FIG. 4D) formed on a first side only extends a portion of the length of the edge member 460, as shown in FIG. 4D. The top and bottom edges of the first and second members 420, 430 are inserted into the recess 465 of the respective edge member 460. The edge members 460 are thereafter bonded to the first and second members 420, 430. In some embodiments, the interfaces between the adjoining edge members 440, 460 may also be bonded together using a localized heating process or chemical process to further seal the photovoltaic module 210 within the panel 400. In some embodiments, the edge members 440, 460 may be used as the frame 108.

In some embodiments, the top and bottom edge of the solar panel 400 may also be sealed by bonding an appropriately sized edge member 240 at either the top end or bottom edge. The top and bottom edges, however, may instead be sealed by injecting a liquid polycarbonate as described in FIGS. 6A-6B.

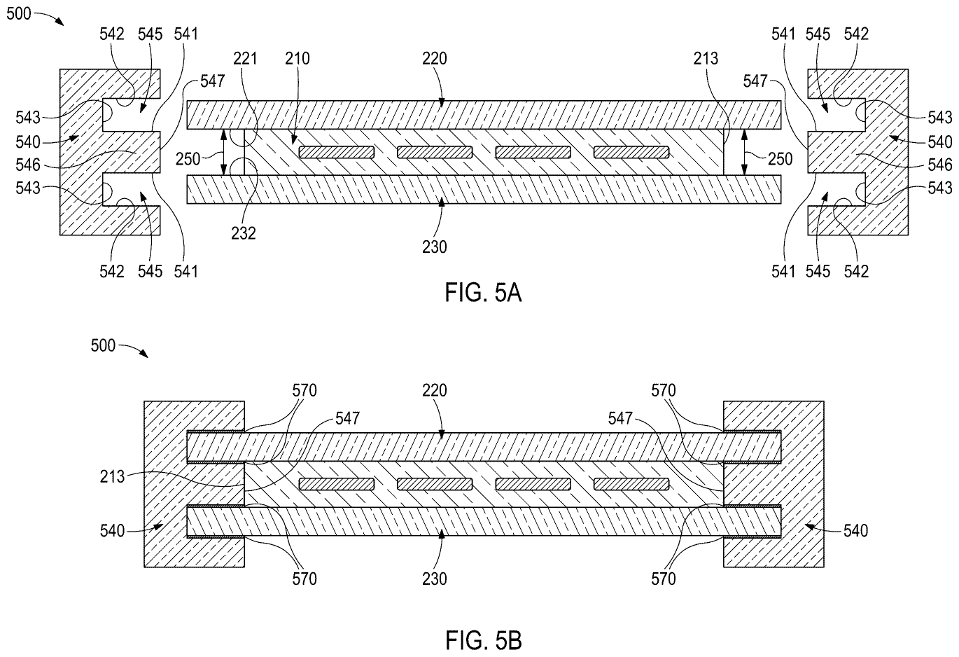

FIGS. 5A and 5B illustrate schematic cross-sectional views of another example solar panel 500, according to one or more additional embodiments of the present disclosure. The solar panel 500 may be similar in some respects to the solar panel 200 of FIGS. 2A-2C and, therefore, may be best understood with reference thereto, where like numerals will correspond to like components not described again in detail. Similar to the solar panel 200, for instance, the solar panel 500 includes the photovoltaic module 210, the first member 220, and the second member 230. The solar panel 500 also includes edge members 540 (e.g., end caps). In some embodiments, the first member 220, the second member 230, and the edge members 540 may be formed from the same material, such as a polycarbonate material. The edge members 540 are bonded (see bond 570 in FIG. 5B) to the first and second members 220, 230 to seal the photovoltaic module 210 from the outside environment.

As shown in FIG. 5A, the edge members 540 are generally “E” shaped members defining two recesses 545 formed on one side and separated by a rib 546. Each recess 545 is defined by a first recess surface 541, a second recess surface 542, and a third recess surface 543. The first recess surfaces 541 partially define the exterior surface of the rib 546. The rib 546 may be sized to be inserted into the edge gap 250 formed between first and second members 220, 230. In some embodiments, the rib 546 is sized such that the first recess surfaces 541 on opposing sides of the rib 546 contact either the first side 221 of the first member 220 or the first side 231 of the second member 230. When the rib 546 is inserted into the edge gap 250, the second recess surfaces 542 oppose, and in some embodiments contact, either the second side 222 of the first member 220 or the second surface 232 of the second member 230. In some embodiments, an end 547 of the rib 546 may contact the exterior surface 213 of the photovoltaic module 210, as shown in FIG. 5B, when the rib 546 is inserted into the edge gap 250.

To assemble the solar panel 500, the photovoltaic module 210 is arranged (sandwiched) between the first and second members 220, 230. For example, the photovoltaic module 210 may be engaged with the opposing first surfaces 221, 232, as shown in FIG. 5A. The edge members 540 are then then engaged with the first and second members 220, 230 such that the rib 546 of each edge member 540 is inserted into the respective edge gap 250, as shown in FIG. 5B. The edge members 540 are then bonded to the first and second members 220, 230 to seal the photovoltaic module 210 from the outside environment. The edge members 540 may be bonded using a process described herein, such as using localized heating to mechanically bond the components together or by a chemical process to cross-link the components together. The bond between the edge member 540 and the first and second members 220, 230 provides a more durable seal as compared to conventional liquid sealants used to seal edges of solar panels.

In some embodiments, the first recess surfaces 541 may be bonded to the respective first or second members 220, 230 using a bonding process described herein. The second recess surfaces 542 may also be bonded to the respective first or second members 220, 230. For example, FIG. 5B illustrates bonds 570 being formed between both sides of the recesses 545 of the edge member 540 with the respective first and second members 220, 230. Each bond 570 shown in FIG. 5B may be formed using the laser welding device 260 shown in FIG. 2C. In some embodiments, however, only one side of each recess 545 may be bonded to a respective member 220, 230, such as only the second recess surfaces 542 being bonded to the respective first and second members 220, 230.

While FIGS. 5A-5B illustrate an edge member 540 on the left and right-hand sides of the solar panel 500, the top and bottom edges of the solar panel 500 (e.g., gap between the first member 220 and second member 230 at the top and bottom ends of the solar panel) may also be sealed by bonding an appropriately sized edge member 240 at either the top end or bottom end. In some embodiments, the top and bottom edges may be enclosed in an edge member similar to edge members 540, such that an edge member is disposed on each side of the solar panel 500. In other words, the solar panel 500 may be framed within four separate edge members in a similar manner as solar panel 400. The adjoining edge members framing the solar panel 500 may be bonded together using a localized heating process or chemical process. The top and bottom edge, however, may instead be sealed by injecting a liquid polycarbonate as described in FIGS. 6A-6B.

FIGS. 6A and 6B illustrate a schematic cross-sectional view of another example solar panel 600, in accordance with one or more additional embodiments of the present disclosure. Solar panel 600 differs from the solar panels 200, 300, 400, and 500 described herein in that the edge seal (see the polycarbonate edge member 640 in FIG. 6B) is formed by injecting a liquid polycarbonate into an edge of the solar panel 600 rather than bonding interfacing surfaces together. The liquid polycarbonate is allowed to solidify which forms a more durable seal against the outside environment as compared to conventional liquid edge sealants used in fabricating solar panels. Additionally, the solidified polycarbonate provides mechanical durability and stability to the solar panel since the edge member 640 fixes the first member 220 to the second member 230.

FIG. 6A illustrates the solar panel 600 prior to applying the liquid polycarbonate and, therefore, prior to forming the polycarbonate edge member 640 (FIG. 6B). As shown, the photovoltaic module 210 is arranged (sandwiched) between the first member and the second members 220, 230. A dispensing gun 660 is then used to inject liquid (e.g., molten) polycarbonate into the edge gap 250 between the first and second members 220, 230 to form the polycarbonate edge member 640. For example, a solid polycarbonate material, such as polycarbonate resin or beads, is placed into the dispensing gun 660. The dispensing gun 660 melts the solid polycarbonate material into a liquid polycarbonate. The liquid polycarbonate exits the dispensing gun 660 and fills the edge gap 250. The heat of the liquid polycarbonate being injected into the edge gap 250 can partially melt the first and second members 220, 230, which promotes cross-linking of the first and second members 220, 230 with the liquid polycarbonate, thereby bonding the polycarbonate edge member 640 to the first and second members 220, 230 once solidified. The polycarbonate is allowed to cool to form the solidified polycarbonate edge member 640, as shown in FIG. 6B. The seal provided by the solidified polycarbonate edge member 640 is more durable than conventional liquid edge sealants used to fabricate solar panels.

The dispensing gun 660 can be used to fill the edge gap 250 on the right-hand and left-hand side of the solar panel 600. The dispensing gun 660 may also be used to fill the gap at the top and bottom edges of the solar panel 600. In other words, the dispensing gun 660 may be used to form a continuous polycarbonate edge member 640 that extends around the perimeter of the photovoltaic module 210 to seal the photovoltaic module 210 from the outside environment.

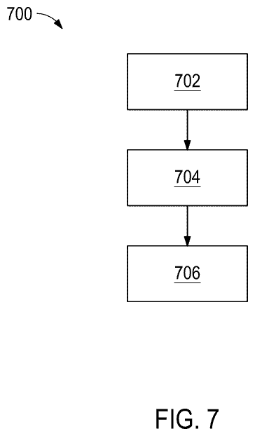

FIG. 7 illustrates a schematic flowchart of an example method 700 of forming a solar panel, according to one or more embodiments.

At operation 702, the photovoltaic module 210 is arranged (sandwiched) between first and second polycarbonate members, such as the first and second members 220, 230.

At operation 704, a polycarbonate edge member is inserted (introduced) into a gap between overhanging portions of the first and second polycarbonate members to engage the polycarbonate edge member with the first and second polycarbonate members. In one embodiment of operation 704, the edge member 240 is insert into the edge gap 250 between the first and second members 220, 230. In one embodiment of operation 704, the rib 546 of edge member 540 is inserted into the edge gap 250 between the first and second members 220, 230. In another embodiment of operation 704, a liquified polycarbonate material is inserted (e.g., injected) into the edge gap 250 between the first and second members 220, 230.

At operation 706, the polycarbonate edge member is bonded to the first and second polycarbonate members. In some embodiments of operation 706, the polycarbonate edge member is bonded to the first and second polycarbonate members by a localized heating process to form a mechanical bond or by a chemical process to form a cross-linked bond. For example, the edge member 240 is bonded to the first and second members 220, 230 by a laser welding process. In some embodiments of operation 706, the polycarbonate edge member, such as polycarbonate edge member 640, is bonded by the liquid polycarbonate cross-linking with the first and second polycarbonate members as the liquid polycarbonate solidifies.

Embodiments disclosed herein include:

A. A solar panel comprises a photovoltaic module having opposing first and second sides. The solar panel further comprises a first polycarbonate member engaged with the first side. The solar panel further comprises a second polycarbonate member engaged with the second side, the photovoltaic module being disposed between the first and second polycarbonate members. The solar panel further comprises a first polycarbonate edge member disposed in a gap between the first and second polycarbonate members, the first polycarbonate edge member being bonded to the first and second polycarbonate members.

B. A solar panel comprises a first polycarbonate member defining a recess disposed between a first interface surface and a second interface surface. The solar panel further comprises a second polycarbonate member contacting the first and second interface surfaces. The solar panel further comprises a photovoltaic module disposed in the recess between the first and second polycarbonate members.

C. A solar panel comprises a first polycarbonate member having opposing first and second ends, and opposing first and second surfaces. The solar panel further comprises a second polycarbonate member having opposing first and second ends, and opposing first and second surfaces. The solar panel further comprises a photovoltaic module disposed between the first and second polycarbonate members, the first and second polycarbonate members being arranged such that the first surface of the first polycarbonate member opposes the first surface of the second polycarbonate member. The solar panel further comprises a first polycarbonate edge member defining a first recess sized to receive the first ends of the first and second polycarbonate members. The solar panel further comprises a second polycarbonate edge member defining a second recess sized to receive the second ends of the first and second polycarbonate members.

Each of embodiments A, B, and C may have one or more of the following additional elements in any combination:

Element 1: the first polycarbonate edge member comprises a strip of polycarbonate inserted within the gap. Element 2: a first interface surface of the first polycarbonate edge member is bonded to the first side of the first polycarbonate member by a mechanical bond formed by a localized heating process. Element 3: the bond between the first polycarbonate edge member and the first and second polycarbonate members is a cross-linked bond formed by a chemical process. Element 4: the first polycarbonate edge member solidified from a liquid state within the gap. Element 5: the gap extends around a perimeter of the photovoltaic module, and the first polycarbonate edge member extends continuously around the perimeter of the photovoltaic module. Element 6: further comprising a second polycarbonate edge member disposed in a second gap between the first polycarbonate member and the second polycarbonate member, the second polycarbonate member being bonded to the first and second polycarbonate members. Element 7: wherein the first polycarbonate member is a polycarbonate strip inserted within the gap and the second polycarbonate member solidified from a liquid state within the second gap. Element 8: the photovoltaic module includes a plurality of photovoltaic elements embedded within a polymer encapsulant. Element 9: the first polycarbonate member is bonded to the first and second interface surfaces by a mechanical bond. Element 10: the first polycarbonate member is bonded to the first and second interface surfaces by a cross-linked bond. Element 11: the first and second interface surfaces are flush with an exterior surface of the photovoltaic module. Element 12: a first side of the first recess is engaged with the second surface of the first polycarbonate member and a second side of the first recess is engaged with the second surface of the second polycarbonate member, and wherein a first side of the second recess is engaged with the second surface of the first polycarbonate member and a second side of the second recess is engaged with the second surface of the second polycarbonate member. Element 13: the first polycarbonate member is in contact with the second polycarbonate member. Element 14: the first and second polycarbonate edge members each define a rib, wherein the rib is disposed between the first and second polycarbonate members. Element 15: wherein the rib of each polycarbonate edge member engages the photovoltaic module. Element 16: wherein the first polycarbonate edge member further includes: a first recess sized to receive the first end the first polycarbonate member, wherein a first side of the first recess is engaged with the first surface of the first polycarbonate member and the second side of the first recess is engaged with the second surface of the first polycarbonate member; and a second recess sized to receive the first end the second polycarbonate member, wherein a first side of the second recess is engaged with the first surface of the second polycarbonate member and the second side of the second recess is engaged with the second surface of the second polycarbonate member. Element 17: the first and second surfaces of each polycarbonate member are welded to the first polycarbonate edge member.

By way of non-limiting example, exemplary combinations applicable to A, B, and C include: Element 1 with Element 2; Element 4 with Element 5, Element 12 with Element 13, Element 14 with Element 15, and Element 16 with Element 17.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

1. A solar panel, comprising:
a photovoltaic module having opposing first and second sides;
a first polycarbonate member engaged with the first side;
a second polycarbonate member engaged with the second side, the photovoltaic module being disposed between the first and second polycarbonate members; and
a first polycarbonate edge member disposed in a gap between the first and second polycarbonate members, the first polycarbonate edge member being bonded to the first and second polycarbonate members.

2. The solar panel of claim 1, wherein the first polycarbonate edge member comprises a strip of polycarbonate inserted within the gap.

3. The solar panel of claim 2, wherein a first interface surface of the first polycarbonate edge member is bonded to the first side of the first polycarbonate member by a mechanical bond formed by a localized heating process.

4. The solar panel of claim 2, wherein the bond between the first polycarbonate edge member and the first and second polycarbonate members is a cross-linked bond formed by a chemical process.

5. The solar panel of claim 1, wherein the first polycarbonate edge member solidified from a liquid state within the gap.

6. The solar panel of claim 5, wherein the gap extends around a perimeter of the photovoltaic module, and the first polycarbonate edge member extends continuously around the perimeter of the photovoltaic module.

7. The solar panel of claim 1, further comprising a second polycarbonate edge member disposed in a second gap between the first polycarbonate member and the second polycarbonate member, the second polycarbonate member being bonded to the first and second polycarbonate members.

8. The solar panel of claim 7, wherein the first polycarbonate member is a polycarbonate strip inserted within the gap and the second polycarbonate member solidified from a liquid state within the second gap.

9. The solar panel of claim 1, wherein the photovoltaic module includes a plurality of photovoltaic elements embedded within a polymer encapsulant.

10-20. (canceled)

21. The solar panel of claim 1, wherein the first polycarbonate edge member comprises:
a first recess receiving a first end of the first polycarbonate member;
a second recess receiving a first end of the second polycarbonate member; and
a first rib separating the first and second recesses disposed in the gap.

22. The solar panel of claim 21, wherein opposing sides of the first rib are bonded to the first and second polycarbonate members.

23. The solar panel of claim 21, wherein the gap is a first gap, further comprising a second polycarbonate edge member disposed in a second gap between the first and second polycarbonate members, the second polycarbonate edge member being bonded to the first and second polycarbonate members.

24. The solar panel of claim 23, wherein the second polycarbonate edge member comprises:
a third recess receiving a second end of the first polycarbonate member opposite the first end thereof;
a fourth recess receiving a second end of the second polycarbonate member opposite the first end thereof; and
a second rib separating the third and fourth recesses disposed in the gap.

25. The solar panel of claim 24, wherein opposing sides of the first rib are bonded to the first and second polycarbonate members.

26. A method of forming a solar panel, comprising:
placing a photovoltaic module having opposing first and second sides between first and second polycarbonate members, wherein the first polycarbonate is engaged with the first side and the second polycarbonate member is engaged with the second side;
inserting a first polycarbonate edge member into a first gap between the first and second polycarbonate members; and
bonding the first polycarbonate edge member to the first and second polycarbonate members.

27. The method of claim 26, wherein the first polycarbonate edge member comprises a strip of polycarbonate inserted within the gap.

28. The method of claim 27, further comprising:
forming a first bond between a first interface surface of the first polycarbonate edge member with the first side of the first polycarbonate member; and
forming a second bond between a second interface surface of the first polycarbonate member with the second side of the second polycarbonate member.

29. The method of claim 28, forming the first and second bonds by a localized heating process.

30. The method of claim 26, further comprising:
inserting a second polycarbonate edge member into a second gap between the first and second polycarbonate members opposite of the first gap; and
bonding the second polycarbonate edge member to the first and second polycarbonate members.
